(19) United States
(12) Patent Application Publication
(10) Pub. No.: US 2022/0272878 A1
(43) Pub. Date: Aug. 25, 2022

(54) COOLING MODULE

(71) Applicant: Sunonwealth Electric Machine Industry Co., Ltd., Kaohsiung City (TW)

(72) Inventors: Alex HORNG, (US); Tso-Kuo YIN, Kaohsiung City (TW); Ming-Tsung LI, Kaohsiung City (TW)

(21) Appl. No.: 17/541,370

(22) Filed: Dec. 3, 2021

(30) Foreign Application Priority Data
Feb. 25, 2021 (TW) 110202059

(51) Int. Cl. H05K 7/20; F28F 9/00; F28F 9/007

(52) U.S. Cl. CPC H05K 7/20927; F28F 9/002; F28F 9/0075

(57) ABSTRACT

A cooling module includes a first casing, a second casing, and a cooling unit. The first casing includes a lower chamber filled with at least one working fluid. The first casing includes a heat source connecting face. The second casing includes an upper chamber. The cooling unit is located between the first and second casings. The cooling unit includes a plurality of tubes. Each of the plurality of tubes includes an end intercommunicating with the lower chamber and another end intercommunicating with the upper chamber, thereby the lower and upper chambers intercommunicate with each other. A plurality of cooling fin units is coupled to outer peripheries of the plurality of tubes. An angle between each of the plurality of tubes and the heat source connecting face is larger than 0° and smaller than 90°, or each of the plurality of tubes is parallel to the heat source connecting face.

### CROSS REFERENCE TO RELATED APPLICATION

The application claims the benefit of Taiwan application serial No. 110202059, filed on Feb. 25, 2021, and the entire contents of which are incorporated herein by reference.

### BACKGROUND OF THE INVENTION

### 1. Field of the Invention

The present invention relates to a cooling module and, more particularly, to a cooling module for an electronic device.

### 2. Description of the Related Art

In a current cooling approach for avoiding local overheating of an electronic device, a vapor chamber is disposed in the electronic device. The vapor chamber can abut a heat generating area of the electronic device. The conventional vapor chamber includes an upper board and a lower board which are coupled together to form a cavity into which a working fluid can be filled. Thus, the heat generated at the heat generating area can spread to the vapor chamber to effectively avoid accumulation in the heat generating area, thereby achieving a cooling effect.

In the above conventional vapor chamber, the heat generating area heats and evaporates the working fluid. The working fluid evaporates to a gaseous state and moves to a side distant to the heat generating area and then condenses, carrying away the heat of the heat generating area. However, since the vapor chamber merely uses the gas-liquid phase change of the working fluid to carry away the heat, the cooling effect of the vapor chamber at the heat generating area is limited, resulting in poor cooling efficiency.

Thus, it is necessary to improve the conventional cooling module.

### SUMMARY OF THE INVENTION

To solve the above problems, it is an objective of the present invention to provide a cooling module with excellent cooling efficiency.

It is another objective of the present invention to provide a cooling module capable of increasing assembling convenience.

It is a further objective of the present invention to provide a cooling module capable of increasing engagement reliability.

It is still another objective of the present invention to provide a cooling module capable of reducing the manufacturing costs.

As used herein, the term “a”, “an” or “one” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

As used herein, the term “coupling”, “engagement”, “assembly”, or similar terms is used to include separation of connected members without destroying the members after connection or inseparable connection of the members after connection. A person having ordinary skill in the art would be able to select according to desired demands in the material or assembly of the members to be connected.

A cooling module according to the present invention includes a first casing, a second casing, and a cooling unit. The first casing includes a lower chamber filled with at least one working fluid. The first casing includes a heat source connecting face. The second casing includes an upper chamber. The cooling unit is located between the first casing and the second casing. The cooling unit includes a plurality of tubes. Each of the plurality of tubes includes an end intercommunicating with the lower chamber and another end intercommunicating with the upper chamber, thereby intercommunicating the lower chamber and the upper chamber. A plurality of cooling fin units is coupled to outer peripheries of the plurality of tubes. An angle between each of the plurality of tubes and the heat source connecting face is larger than 0° and smaller than 90°, or each of the plurality of tubes is parallel to the heat source connecting face.

Thus, in operation of the cooling module according to the present invention, the liquid working fluid in the lower chamber can absorb heat to evaporate into the gaseous state. Next, the gaseous working fluid enters the upper chamber via the plurality of tubes. Since the angle between each of the plurality of tubes and the heat source connecting face is larger than 0° and smaller than 90° or each of the plurality of tubes is parallel to the heat source connecting face, the working fluid in the upper chamber condensing from the gaseous state into the liquid state can flow downwards back into the lower chamber under the gravitational force. This increases the recycling and recirculating functions of the condensed liquid. Furthermore, the provision of the plurality of cooling fin units provides a larger contact area for the heat in the plurality of tubes and the plurality of cooling fin units, increasing the cooling effect.

In an example, the first casing may include a casing seat and a first positioning board. The first positioning board may be coupled to the casing seat to form the lower chamber. The second casing may include a lid and a second positioning board. The lid may be coupled to the second positioning board to form the upper chamber. Thus, the structure is simple and easy to assemble, increasing the assembling convenience.

In an example, the first casing may include a casing seat and a first positioning board. The casing seat may include a bottom inner face therein. The bottom inner face may face an opening of the casing seat. The first positioning board covers the opening. The heat source connecting face may be located on an annular wall of the casing seat. The area of the opening may be larger than the area of the bottom inner face. Thus, the width of the first casing decreases downwards to maintain the working fluid at a certain liquid level, assuring that the working fluid can fully absorb the heat of the heat source.

In an example, the first casing seat may include a casing seat. The casing seat may include a bottom portion and an annular wall connected to the bottom portion. The heat source connecting face may be located on the bottom portion or the annular wall. Thus, the structure is simple and easy to manufacture, reducing the manufacturing costs.

In an example, the heat source connecting face may be located on the annular wall. The casing seat may bend from a portion of the bottom portion towards the lower chamber to form a first bending portion and may bend from a portion of the annular wall towards the lower chamber to form a second bending portion. The first bending portion and the second bending portion may together form a recessed portion. Thus, during installation of the cooling module according to the present invention, the casing seat uses the recessed portion to avoid other parts, such that the cooling module can be mounted, aligned, and adjusted in height in response to the location of the heat source, increasing installation convenience.

In an example, the second bending portion is inclined. Thus, the working fluid can flow back to the bottom portion of the casing seat more easily.

In an example, the heat source connecting face may be located on the bottom portion. The height of the annular wall may gradually increase from a side of the casing seat towards another side of the casing seat. The plurality of tubes is coupled with the first casing to form the angle. Thus, the structure is simple and easy to manufacture, reducing the manufacturing costs.

In an example, the first casing may include a casing seat and at least one engaging portion. The at least one engaging portion is connected to the casing seat. The at least one engaging portion is adapted to be securely coupled to a pre-determined position. Thus, the heat source connecting face of the casing seat can easily be in thermal connection with the heat source, increasing convenience in use.

In an example, the first casing may include a first positioning board. The second casing may include a second positioning board. The plurality of tubes is coupled with the first positioning board and the second positioning board. Thus, the plurality of tubes can be stably positioned between the first casing and the second casing, increasing engaging stability.

In an example, the at least one working fluid includes two or more working fluids. Thus, using two or more working fluids having different boiling points may increase the circulating speed of the working fluids in the gas phase and the liquid phase, increasing the cooling effect.

In an example, the at least one working fluid is an electrically non-conductive liquid. Thus, short circuit of the system circuit will not occur even if the at least one working fluid leaks.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is an exploded, perspective view of a cooling module of a first embodiment according to the present invention.

FIG. 2 is a cross sectional view of the cooling module of the first embodiment according to the present invention after assembly.

FIG. 3 is a cross sectional view of a cooling module of a second embodiment according to the present invention after assembly.

FIG. 4 is a cross sectional view of the cooling module of the second embodiment according to the present invention, with a side of an annular wall inclinedly connected to an intersection between a bottom portion and the annular wall having a heat source connecting face, forming a diagonal pattern

FIG. 5 is a cross sectional view of a cooling module of a third embodiment according to the present invention after assembly.

FIG. 6 is a cross sectional view of the cooling module of the third embodiment according to the present invention, with a second bending portion being inclined.

In the various figures of the drawings, the same numerals designate the same or similar parts. Furthermore, when the terms “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the invention.

### DETAILED DESCRIPTION OF THE INVENTION

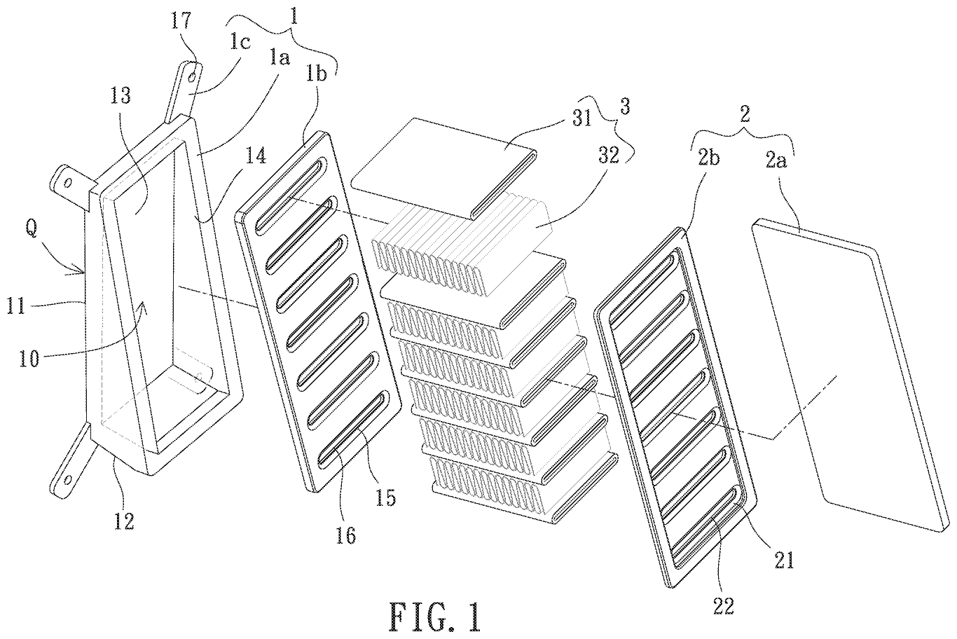

With reference to FIG. 1, a cooling module of a first embodiment according to the present invention includes a first casing 1, a second casing 2, and a cooling unit 3. The cooling unit 3 is located between the first casing 1 and the second casing 2.

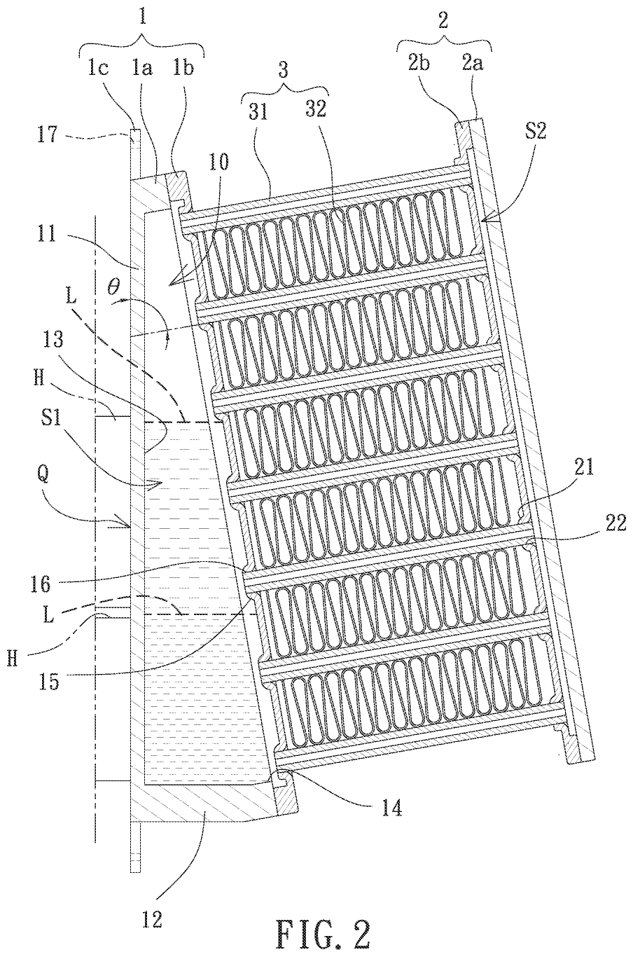

With reference to FIGS. 1 and 2, the first casing 1 includes a lower chamber S1. The present invention is not limited to the formation method of the lower chamber S1. In this embodiment, the first casing 1 may have a casing seat 1a and a first positioning board 1b. The first positioning board 1b is coupled to the casing seat 1a to form the lower chamber S1. The lower chamber S1 is filled with a working fluid L. The working fluid L can be water, alcohol, or any liquid with a low boiling point. Preferably, the working fluid L is an electrically non-conductive liquid. Thus, short circuit of the system will not occur even if the working fluid L leaks. The working fluid L absorbs heat and evaporates from a liquid state into a gaseous state, thereby using the transition between the gas phase and the liquid phase of the working fluid L to achieve heat transfer.

Specifically, the first casing 1 includes a heat source connecting face Q for thermal connection with a heat source H. The heat source H can be a server, a computer, or a central processor of other electric appliance, or electronic elements or a circuit board, which generate heat during operation. More specifically, in an option of the lower chamber S1, the casing seat 1a has a receiving space 10, and the first positioning board 1b is coupled to the casing seat 1a to form the lower chamber S1. As an example, the casing seat 1a of this embodiment may include a bottom portion 11 and an annular wall 12 connected to the bottom portion 11. The heat source connecting face Q can be located on the bottom portion 11. The bottom portion 11 and the annular wall 12 together define the receiving space 10.

In other embodiments, a receiving space 10 can be provided on the first positioning board 1b rather than the casing seat 1a. Alternatively, each of the casing seat 1a and the first positioning board 1b can include a receiving space 10, which together define a larger space for receiving when coupled. The present invention is not limited in this regard. After bonding the heat source connecting face Q with a thermally conductive gel, the casing seat 1a can then be in thermal connection with the heat source H. Alternatively, the whole casing seat 1a can be selected to be directly made of a metal material with a high thermal conductivity, such as copper or aluminum.

It should be noted that the lower chamber S1 may be filled with at least one working fluid L. For example, the lower chamber S1 may be filled with one, two, three or more kinds of working fluids L. As shown in FIG. 2, when different kinds of working fluids L, which do not dissolve in each other, are used together, the working fluids L can be separated into layers due to different density, thereby cooling heat sources H with different cooling demands. Thus, since different working fluids L have different boiling points, the circulating speed of the working fluids L in the gas phase and the liquid phase may be increased, thereby increasing the cooling effect. Furthermore, regarding the working fluid L in the lower chamber S1, a working fluid L of a different boiling temperature can be filled according to the need of the heat source H. Thus, when the cooling demand is not high, an inexpensive working fluid L can be selected to save the costs.

Furthermore, the casing seat 1a may include a bottom inner face 13 therein. The bottom inner face 13 faces an opening 14 of the casing seat 1a. The first positioning board 1b may be coupled with atop edge of the annular wall 12 to cover the opening 14. Furthermore, the height of the annular wall 12 gradually increases from a side of the casing seat 1a towards another side of the casing seat 1a, such that the first positioning board 1b and the bottom portion 11 are not parallel to each other.

Furthermore, the first positioning board 1b may have a plurality of first coupling portions 15. Each of the plurality of first coupling portions 15 has a first through-hole 16. The first through-holes 16 intercommunicate with the lower chamber S1. Furthermore, the first casing 1 may include at least one engaging portion 1c which can be connected to the casing seat 1a. The at least one engaging portion 1c may include an engaging hole 17 by which the at least one engaging portion 1c is adapted to be securely coupled to a pre-determined position, such that the heat source connecting face Q can easily be in thermal contact with the heat source H.

The second casing 2 includes an upper chamber S2. The present invention is not limited to the formation method of the upper chamber S2. In this embodiment, the second casing 2 may include a lid 2a and a second positioning board 2b. The lid 2a is coupled to the second positioning board 2b to form the upper chamber S2. Furthermore, the second positioning board 2b may include a plurality of second coupling portions 21. Each of the plurality of second coupling portions 21 may include a second through-hole 22. The second through-holes 22 intercommunicate with the upper chamber S2.

With reference to FIG. 1, the cooling unit 3 is located between the first casing 1 and the second casing 2. The cooling unit 3 includes a plurality of tubes 31 and a plurality of cooling fin units 32. Each of the plurality of cooling fin units 32 can be formed by bending a single metal sheet into winding fins or by coupling superimposed fins together. The present invention is not limited in this regard. The plurality of cooling fin units 32 can be made of a metal material having a high thermal conductivity. The plurality of cooling fin units 32 is coupled to outer peripheries of the plurality of tubes 31. The plurality of cooling fin units 32 is disposed side by side between the first positioning board 1b and the second positioning board 2b. The plurality of cooling fin units 32 and the plurality of tubes 31 are alternatingly disposed.

With reference to FIGS. 1 and 2, specifically, each of the plurality of tubes 31 includes an end that may abut an associated first coupling portion 15 of the first positioning board 1b and that intercommunicates with the lower chamber S1 via an associated first through-hole 16 of the first positioning board 1b. Each of the plurality of tubes 31 further includes another end that abuts an associated second coupling portion 21 of the second positioning board 2b and that intercommunicates with the upper chamber S2 via an associated second through-hole 22 of the second positioning board 2b. Thus, each of the plurality of tubes 31 can be coupled with the first positioning board 1b and the second positioning board 2b, and the lower chamber S1 and the upper chamber S2 can intercommunicate with each other. When each of the plurality of tubes 31 is coupled to the first positioning board 1b of the first casing 1, each of the plurality of tubes 31 is at an angle θ to the heat source connecting face Q. The angle θ is larger than 0° and smaller than 90°.

With reference to FIG. 2, in operation of the cooling module, the heat source connecting face Q at the bottom portion 11 of the first casing 1 is in thermal connection with the heat source H. The liquid working fluid L in the lower chamber S1 can absorb heat to evaporate into the gaseous state, such that the working fluid L in the lower chamber S1 absorbs the heat at the heat source H. Next, the gaseous working fluid L enters the upper chamber S2 via the plurality of tubes 31. Since the angle θ between each of the plurality of tubes 31 and the heat source connecting face Q is larger than 0° and smaller than 90°, each of the plurality of tubes 31 may be disposed in an inclined manner, such that the working fluid L in the upper chamber S2 condensing from the gaseous state into the liquid state can flow downwards back into the lower chamber S1 under the gravitational force. This increases the recycling and recirculating abilities of the condensed liquid, such that the working fluid L can fully absorb the heat of the heat source H, achieving excellent cooling effect. Furthermore, the provision of the plurality of cooling fin units 32 provides a larger contact area for the heat in the plurality of tubes 31 and the plurality of cooling fin units 32, increasing the cooling effect.

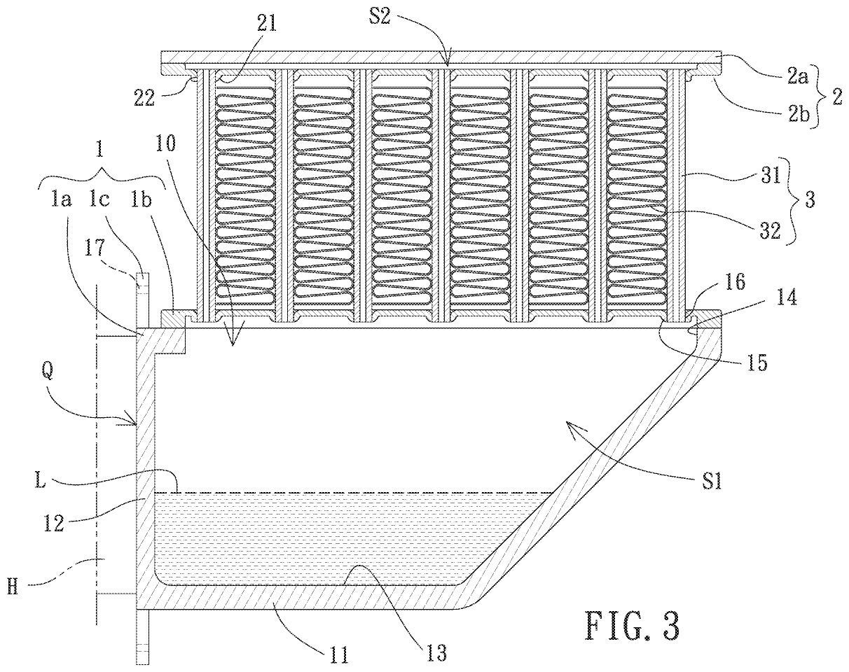

With reference to FIG. 3 showing a cooling module of a second embodiment of the present invention, the heat source connecting face Q may be located on the annular wall 12, and each of the plurality of tubes 31 is parallel to the heat source connecting face Q, such that each of the plurality of tubes 31 is perpendicular to the bottom portion 11 of the first casing 1. In operation of the cooling module, the liquid working fluid L in the lower chamber S1 can absorb heat to evaporate into a gaseous state, such that the working fluid L in the lower chamber S1 absorbs the heat at the heat source H. Next, the gaseous working fluid L enters the upper chamber S2 via the plurality of tubes 31. The working fluid L in the upper chamber S2 condensing from the gaseous state into the liquid state can directly flow downwards back into the lower chamber S1 under the gravitational force. This increases the recycling and recirculating abilities of the condensed liquid, such that the working fluid L can fully absorb the heat of the heat source H.

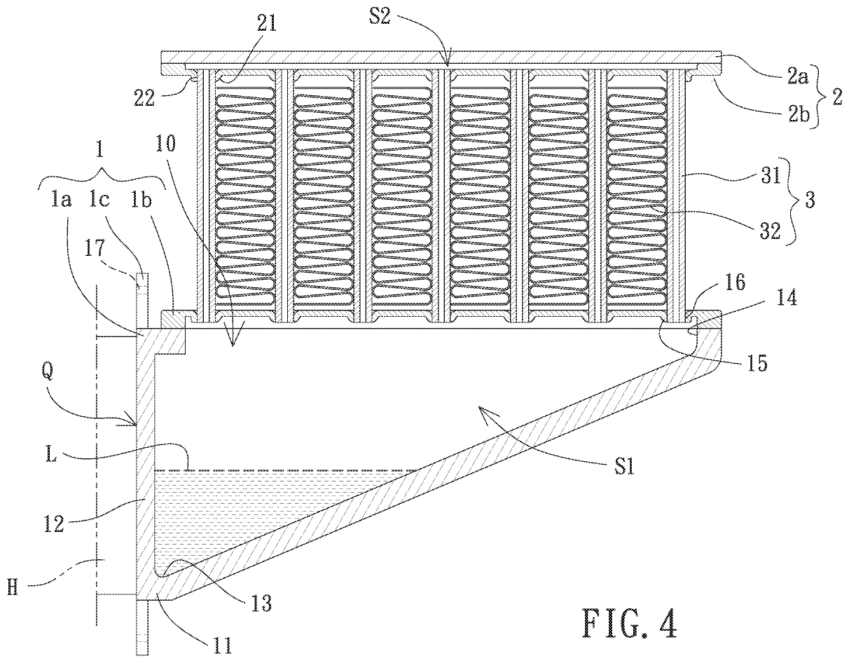

Furthermore, in this embodiment, a side of the annular wall 12 may be inclinedly connected to the bottom portion 11, as shown in FIG. 3. In another embodiment, as shown in FIG. 4, a side of the annular wall 12 is inclinedly connected to an intersection between the bottom portion 11 and the annular wall 12 having the heat source connecting face Q, forming a diagonal pattern. Thus, a larger space can be provided below the casing seat 1a to avoid other parts, such that the cooling module can be mounted, aligned, and adjusted in height in response to the location of the heat source H. Furthermore, the area of the opening 14 of the first casing 1 is preferably larger than the area of the bottom inner face 13, such that the width of the first casing 1 decreases downwards to maintain the working fluid L at a certain liquid level. Thus, the working fluid L can fully absorb the heat of the heat source H to accelerate the condensation of the working fluid L in the lower chamber S1 from the gaseous state into the liquid state for absorbing heat. As a result, the working fluid L in the lower chamber S1 can cool the heat source H.

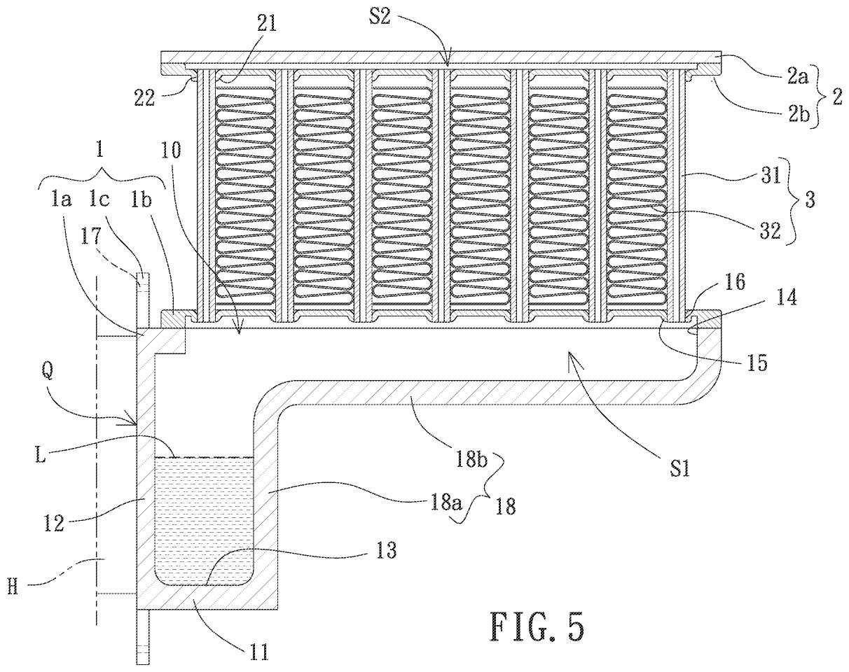

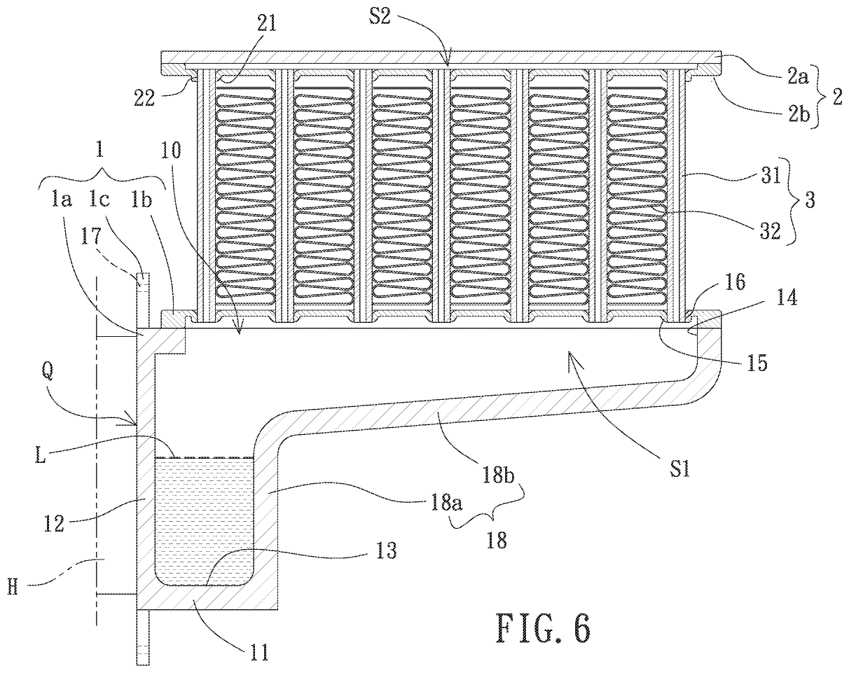

With reference to FIG. 5 showing a cooling module of a third embodiment according to the present invention, the heat source connecting face Q may be located on the annular wall 12. The casing seat 1a may bend from a portion of the bottom portion 11 towards the lower chamber S1 to form a first bending portion 18a and may bend from a portion of the annular wall 12 towards the lower chamber S1 to form a second bending portion 18b, such that the first bending portion 18a and the second bending portion 18b together form a recessed portion 18. In this embodiment, the second bending portion 18b may be rectilinear (namely, the second bending portion 18b is parallel to the lid 2a), as shown in FIG. 5. In another embodiment, the second bending portion 18b may be inclined, as shown in FIG. 6, such that the working fluid L can flow more easily back to the bottom portion 11 of the casing seat 1a. The present invention is not limited in this regard. Thus, in installation of the cooling module according to the present invention, the recessed portion 18 of the casing seat 1a can be used to avoid other parts, such that the cooling module can be mounted, aligned, and adjusted in height in response to the location of the heat source H. Thus, the cooling unit 3 can be easily mounted in a limited space and, thus, can be cooperated with various installation spaces.

In view of the foregoing, in operation of the cooling module according to the present invention, the liquid working fluid in the lower chamber can absorb heat to evaporate into the gaseous state. Next, the gaseous working fluid enters the upper chamber via the plurality of tubes. Since the angle between each of the plurality of tubes and the heat source connecting face is larger than 0° and smaller than 90° or each of the plurality of tubes is parallel to the heat source connecting face, the working fluid in the upper chamber condensing from the gaseous state into the liquid state can flow downwards back into the lower chamber under the gravitational force. This increases the recycling and recirculating functions of the condensed liquid. Furthermore, the provision of the plurality of cooling fin units provides a larger contact area for the heat in the plurality of tubes and the plurality of cooling fin units, increasing the cooling effect.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A cooling module comprising:
a first casing including a lower chamber filled with at least one working fluid, wherein the first casing includes a heat source connecting face;
a second casing including an upper chamber; and
a cooling unit located between the first casing and the second casing, wherein the cooling unit includes a plurality of tubes, wherein each of the plurality of tubes includes an end intercommunicating with the lower chamber and another end intercommunicating with the upper chamber, thereby the lower chamber and the upper chamber intercommunicate with each other, wherein a plurality of cooling fin units is coupled to outer peripheries of the plurality of tubes, and wherein an angle between each of the plurality of tubes and the heat source connecting face is larger than 0° and smaller than 90°, or each of the plurality of tubes is parallel to the heat source connecting face.

2. The cooling module as claimed in claim 1, wherein the first casing includes a casing seat and a first positioning board, wherein the first positioning board is coupled to the casing seat to form the lower chamber, wherein the second casing includes a lid and a second positioning board, and wherein the lid is coupled to the second positioning board to form the upper chamber.

3. The cooling module as claimed in claim 1, wherein the first casing includes a casing seat and a first positioning board, wherein the casing seat includes a bottom inner face therein, wherein the bottom inner face faces an opening of the casing seat, wherein the first positioning board covers the opening, wherein the heat source connecting face is located on an annular wall of the casing seat, and wherein an area of the opening is larger than an area of the bottom inner face.

4. The cooling module as claimed in claim 1, wherein the first casing includes a casing seat, wherein the casing seat includes a bottom portion and an annular wall connected to the bottom portion, and wherein the heat source connecting face is located on the bottom portion or the annular wall.

5. The cooling module as claimed in claim 4, wherein the heat source connecting face is located on the annular wall, wherein the casing seat bends from a portion of the bottom portion towards the lower chamber to form a first bending portion and bends from a portion of the annular wall towards the lower chamber to form a second bending portion, and wherein the first bending portion and the second bending portion together form a recessed portion.

6. The cooling module as claimed in claim 5, wherein the second bending portion is inclined.

7. The cooling module as claimed in claim 4, wherein the heat source connecting face is located on the bottom portion, wherein a height of the annular wall gradually increases from a side of the casing seat towards another side of the casing seat, and wherein the plurality of tubes is coupled with the first casing to form the angle.

8. The cooling module as claimed in claim 1, wherein the first casing includes a casing seat and at least one engaging portion, wherein the at least one engaging portion is connected to the casing seat, and wherein the at least one engaging portion is configured to be securely coupled to a pre-determined position.

9. The cooling module as claimed in claim 1, wherein the first casing includes a first positioning board, wherein the second casing includes a second positioning board, and wherein the plurality of tubes is coupled with the first positioning board and the second positioning board.

10. The cooling module as claimed in claim 1, wherein the at least one working fluid includes two or more working fluids.

11. The cooling module as claimed in claim 1, wherein the at least one working fluid is an electrically non-conductive liquid.
